(19) United States
(12) Patent Application Publication
(10) Pub. No.: US 2022/0140571 A1
(43) Pub. Date: May 5, 2022

(54) COMPACT OPTICAL MODULE

(71) Applicant: STMicroelectronics Ltd, Netanya (IL)

(72) Inventor: Alex DOMNITS, Gedera (IL)

(73) Assignee: STMicroelectronics Ltd, Netanya (IL)

(21) Appl. No.: 17/083,548

(22) Filed: Oct. 29, 2020

(51) Int. Cl. H01S 5/40; H01S 5/022; H01S 5/00; G02B 27/01

(52) U.S. Cl. CPC H01S 5/4012; H01S 5/02292; G02B 2027/0178; H01S 5/0014; G02B 27/0172; H01S 5/4093

(57) ABSTRACT

A compact optical package includes an RGB laser unit containing red, green, and blue laser diodes within a single package, with three lenses adjacent the RGB laser unit to collimate red, green, and blue laser light emitted by the red, green, and blue laser diodes. A beam combiner combines the red, green, and blue laser light into a single RGB laser beam and also outputs a lower power feedback beam. The compact optical package also includes a movable mirror apparatus, and a fixed folding mirror upon which the single RGB laser beam output by the beam splitter impinges and reflects the single RGB laser beam toward the movable mirror apparatus. The movable mirror apparatus directs the single RGB laser beam through an exit window and to scan the single RGB laser beam in a scan pattern to form at least one desired image on a target.

### TECHNICAL FIELD

This disclosure is directed to the field of laser scanning projectors and, in particular, to a compact optical module for use in laser scanning projectors.

### BACKGROUND

A laser scanning projector or “picoprojector” is a small, portable electronic device. Picoprojectors are typically paired to, or incorporated within, user devices such as smart glasses, smartphones, tablets, laptops, or digital cameras, and used to project virtual and augmented reality, documents, images, or video stored on those user devices onto a projection surface, such as a wall, light field, holographic surface, or inner display surface of virtual or augmented reality glasses.

Such picoprojectors typically include a projection subsystem and an optical module. The paired user device serves an image stream (e.g., a video stream) to the projection subsystem. The projection subsystem properly drives the optical module so as to project the image stream onto the projection surface for viewing.

In greater detail, typical optical modules are comprised of a laser source and one or more microelectromechanical (MEMS) mirrors to scan the laser beam produced by the laser source across the projection surface in a projection pattern. By modulating the laser beam according to its position on the projection surface, while the laser beam is scanned in the projection pattern, the image stream is displayed. Commonly, at least one lens focuses the beam after reflection by the one or more MEMS mirrors, and before the laser beam strikes the projection surface, although optical modules of other designs may be used.

The projection subsystem controls the driving of the laser source and the driving of the movement of the one or more MEMS mirrors. Typically, the driving of movement of one of MEMS mirrors is at, or close to, the resonance frequency of that MEMS mirror, and the driving of movement of another of the MEMS mirrors is performed linearly and not at resonance.

While existing picroprojector systems are usable within virtual reality headsets and augmented reality glasses, due to the fact such devices are carried by the user's head, it is desired for such devices to be as light as possible. Additionally, particularly in the case of augmented reality glasses, it is also for such devices to be as compact as possible, since a pair of augmented reality glasses that externally appears no different than a common pair of eyeglasses would be highly commercially desirable. Current optical modules are larger and heavier than desired for virtual reality and augmented reality applications, and as such, further development into ways to shrink and lighten such optical modules is necessary.

### SUMMARY

Disclosed herein is an optical package, including a laser unit containing one or more laser diodes within a single package, one or more lenses adjacent the laser unit and configured to collimate laser light emitted by the one or more laser diodes of the laser unit, a beam combiner configured to combine the laser light from the one or more laser diodes into a single laser beam and to also output a lower power feedback beam, a movable mirror apparatus, and a fixed folding mirror upon which the single laser beam output by the beam combiner impinges and which is configured to reflect the single laser beam toward the movable mirror apparatus. The movable mirror apparatus is configured to direct the single laser beam through an exit window and to scan the single laser beam in a scan pattern to form at least one desired image on a target adjacent the optical package.

In some instances, the laser unit contains red, green, and blue laser diodes within a single package that lases to generate red, green, and blue laser light that is initially shone through a prism within the laser unit and which exit the prism to impinge upon the one or more lenses. In these instances, the one or more lenses are first, second, and third lenses upon which the red, green, and blue lasers impinge, and the single laser beam is a RGB laser beam. The red, green, and blue laser diodes may each be formed within respective dies contained within the single package of the laser unit, and the respective die into which the red, green, and blue laser diodes may be formed are separated from one another by free space within the laser unit. Also, the movable mirror apparatus may include a horizontal mirror upon which the RGB laser beam, as reflected by the folding mirror, impinges, and the horizontal mirror may reflect the RGB laser beam toward a vertical mirror that reflects the RGB laser beam out an exit window in the optical package.

The horizontal mirror may be driven at resonance and the vertical mirror may be driven linearly. The vertical mirror may be arranged such that the RGB laser beam exits the exit window at a desired keystone angle.

A photodiode may receive the low power feedback beam.

The beam combiner may include a single beam splitter unit arranged such that the laser light emitted by the one or more laser diodes enters into outputs of the beam splitter, such that the low power feedback beam exits from another output of the beam splitter, and such that the single laser beam exists from the input of the beam splitter.

The beam combiner may instead include first, second, and third discrete dichroic beam combiners spaced apart from one another.

Also disclosed herein is an augmented reality package, including a printed circuit board containing laser driver circuitry and mirror driver circuitry, and a compact optical package mechanically connected to the printed circuit board and electrically connected to the laser driver circuitry and mirror driver circuitry. The compact optical package includes an RGB laser unit containing red, green, and blue laser diodes within a single package, the RGB laser unit being electrically connected to the laser driver circuitry. The compact optical package also includes three lenses adjacent the RGB laser unit and configured to collimate red, green, and blue laser light emitted by the red, green, and blue laser diodes of the RGB laser unit. A beam combiner within the compact optical package is configured to combine the red, green, and blue laser light into a single RGB laser beam and to also output a lower power feedback beam. A movable mirror apparatus within the compact optical package is electrically connected to the mirror driver circuitry, and there is a fixed folding mirror upon which the single RGB laser beam output by the beam splitter impinges and which is configured to reflect the single RGB laser beam toward the movable mirror apparatus. The movable mirror apparatus is configured to, under control of the mirror driver circuitry, direct the single RGB laser beam through an exit window and to scan the single RGB laser beam in a scan pattern to form at least one desired image on a target of the augmented reality package.

The red, green, and blue laser diodes may each be formed within respective dies contained within the single package of the RGB laser unit. The respective die into which the red, green, and blue laser diodes are formed may be separated from one another by free space within the RGB laser unit.

The movable mirror apparatus may include a horizontal mirror upon which the RGB laser beam, as reflected by the folding mirror, impinges. The horizontal mirror may reflect the RGB laser beam toward a vertical mirror that reflects the RGB laser beam out an exit window in the compact optical package toward the target.

The horizontal mirror may be driven at resonance and the vertical mirror may be driven linearly. The vertical mirror may be arranged such that the RGB laser beam exits the exit window at a desired keystone angle.

A photodiode may receive the low power feedback beam.

The beam combiner may include a single beam splitter unit arranged such that the red, green, and blue laser light enters into outputs of the beam splitter, such that the low power feedback beam exits from another output of the beam splitter, and such that the single RGB laser beam exists from the input of the beam splitter.

As an alternative, the beam combiner may include first, second, and third discrete dichroic beam combiners spaced apart from one another.

### BRIEF DESCRIPTION OF THE DRAWINGS

FIG. 1 is a diagrammatical representation of a first variant of a compact optical module disclosed herein.

FIG. 2 contains front and rear perspective views of the RGB laser package used in the compact optical modules disclosed herein.

FIG. 3 is a diagrammatical representation of a second variant of a compact optical module disclosed herein.

FIG. 4 is a perspective diagram of the compact optical module of FIG. 1.

FIG. 5 is diagrammatical representation of the vertical mirror, horizontal mirror, and folding mirror of FIG. 1 with a keystone angle of 0°.

FIG. 6 is diagrammatical representation of the vertical mirror, horizontal mirror, and folding mirror of FIG. 1 with a keystone angle of 5°.

FIG. 7 is diagrammatical representation of the vertical mirror, horizontal mirror, and folding mirror of FIG. 1 with a keystone angle of 14°.

FIG. 8 is a perspective view of the compact optical module of FIG. 1 as installed within a housing, in which the dimensions of the compact optical module are shown.

FIG. 9 is a perspective view of an augmented reality unit including the compact optical module of FIG. 1.

FIG. 10 is a perspective view of a pair of augmented reality glasses including the augmented reality unit of FIG. 9.

### DETAILED DESCRIPTION

The following disclosure enables a person skilled in the art to make and use the subject matter disclosed herein. The general principles described herein may be applied to embodiments and applications other than those detailed above without departing from the spirit and scope of this disclosure. This disclosure is not intended to be limited to the embodiments shown, but is to be accorded the widest scope consistent with the principles and features disclosed or suggested herein.

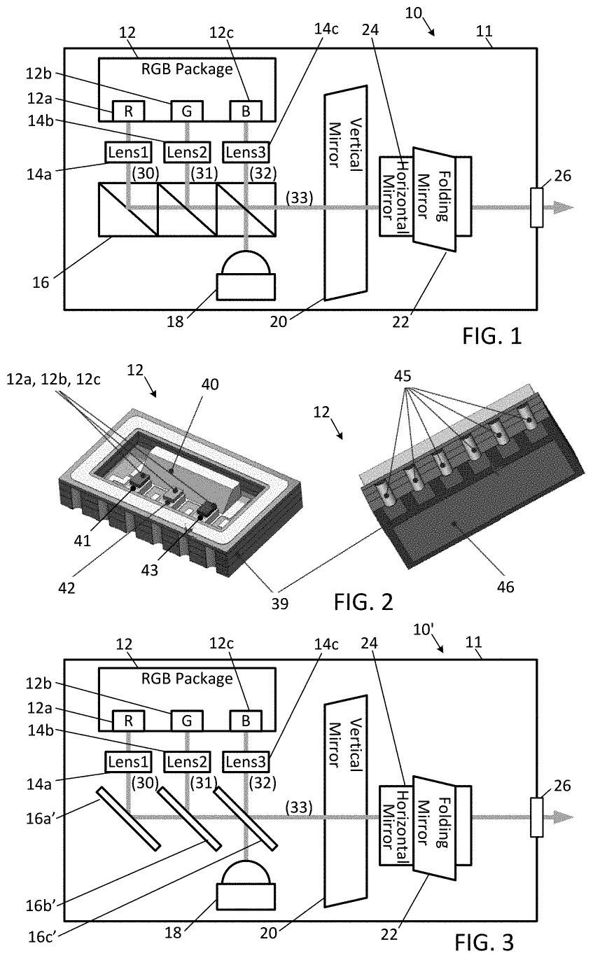

A compact optical module 10 is now described with reference to FIG. 1. The compact optical module 10 includes a housing 11 carrying a compact RGB laser package 12 that includes a red laser diode 12a, green laser diode 12b, and blue laser diode 12c therein.

Details of the compact RGB laser package 12 are shown in FIG. 2. The compact RGB laser package 12 includes an aluminum nitride body 39, on a front face of which are aluminum nitride sub-mounts 41, 42, and 43. The red laser diode 12a is mounted to the first aluminum nitride sub-mount 41, green laser diode 12b is mounted to the second aluminum nitride sub-mount 42, and the blue laser diode 12c is mounted to the third aluminum nitride sub-mount 43. The laser diodes 12a, 12b, and 12c themselves are each formed in their own die. A single glass prism 40 is mounted to the front side of the aluminum nitride body 39, and serves to help focus the red, green, and blue laser beams respectively emitted by the red laser diode 12a, green laser diode 12b, and blue laser diode 12c, although it should be appreciated that in some instances, the element 40 may instead be three glass prisms, one for each laser diode 12a, 12b, and 13c. On the back face of the aluminum nitride body 39, electrical pads 45 are mounted, which provide connections to the red laser diode 12a, green laser diode 12b, and blue laser diode 12c. A thermal pad 46 is mounted on the back face of the aluminum nitride body 39 and makes contact with the housing 11 at the location therein where the compact RGB laser package 12 is carried. The physical dimensions of the housing 11 may be, for example, 5.3 mm in width, 4 mm in depth, and 1.25 mm in height. Prior art systems utilize individually packaged laser diodes, each of which is nearly the size of the RGB laser package 12 used herein; thus the RGB laser package 12 provides a large amount of savings in terms of space and weight. Naturally, the RGB laser package 12 and housing 11 may have other dimensions, and the given dimensions are just examples.

Returning to FIG. 1, alignment lenses 14a, 14b, and 14c are carried within the housing 11 adjacent the RGB laser package 12, and serve to collimate the laser beams 30, 31, and 32 respectively generated by the red laser diode 12a, green laser diode 12b, and blue laser diode 12c in operation. The alignment lenses 14a, 14b, and 14c are set such that the laser spots would overlap at a certain distance, for example, at a 450 mm focal distance. In addition, the maximum angular deviation between any two laser spots should helpfully be no more than 0.2°, and the maximum deviation between all laser spots should helpfully be no more than 0.5°. The spot size produced by the red laser diode 12a, after focusing by the alignment lens 14a, is to be around 830×650 microns; the spot size produced by the blue laser diode 12b, after focusing by the alignment lens 14b, is to be around 800×600 microns; and the spot size produced by the green laser diode 12c, after focusing by the alignment lens 14c, is to be around 780×550 microns. If the focal distance is changed from this example for a particular application, the spot size changes accordingly. The alignment lenses 14a, 14b, and 14c may have a numerical aperture of 0.38, with an effective focal length of 2 mm, and a 1 mm diameter, and may be coated with anti-reflective coating that allows light in the range of 400 nm-700 nm to pass but rejects other light. The alignment lenses 14a, 14b, and 14c may have a generally cylindrical cross section, with a flat rear surface and a convex front surface, or, in some cases, may have an aspherical shape. The effective focal length and diameter of the alignment lenses 14a, 14b, and 14c can be altered as desired for specific applications. For example, the alignment lenses 14a, 14b, and 14c may be 1.5 mm in diameter. Also appreciate that in some cases, the alignment lenses 14a, 14b, and 14c may have different diameters from one another, or one of the alignment lenses may have a different diameter than the other two alignment lenses.

A 4:1 beam splitter 16 is carried within the housing 11 adjacent the alignment lenses 14a, 14b, and 14c. This beam splitter 16 is a single rectangularly shaped unit formed of three square units, each square unit being comprised of two triangular prisms having their bases affixed to one another. The overall dimensions of the beam splitter may be, for example, 6 mm in length, 2 mm in depth, and 2.5 mm in height. Naturally, these dimensions are just examples, and the beam splitter 16 may instead of other dimensions.

The prisms of the beam splitter 16 that serve to reflect the laser beams 30 and 31 are arranged so as to reflect as close to 100% of those beams as possible along a trajectory out the right side of the beam splitter 36 to help form the combined RGB laser beam 33, while the prisms of the beam splitter 16 that serve to reflect the laser beam 32 is arranged so as to reflect about 98% of the laser beam 32 out the right side of the beam splitter 36 to form the combined RGB laser beam 33, while passing about 2% of the laser beam 32 through to reach a photodiode 18 used to provide feedback for the system driving the laser diodes 12a, 12b, and 12c of the RGB laser package 12.

Note that while the beam splitter 16 here is used to combine the laser beams 30, 31, and 32 to form the RGB laser beam 33, the beam splitter 16 is still technically a 4:1 beam splitter, as if a beam 33 were to be input into the right side (the output) of the beam splitter 16, the beam splitter would split it to produce the beams 32 (exiting toward the lens 14c and toward the photodiode 18), 31, and 30. Thus, despite its use as a beam combiner, the component 16 is indeed a beam splitter 16.

A vertical mirror 20, horizontal mirror 24, and folding mirror 22 are adjacent the beam splitter 16, and collectively are used to reflect the RGB laser beam 33 out an exit window 26 on a housing 11 and onto a display surface. Note that the position of the folding mirror 22 is fixed during operation, while the horizontal mirror 24 is driven to oscillate at its resonance frequency and the vertical mirror 22 is driven linearly. Therefore, the purpose of the folding mirror 22 is simply to “fold” the path of the RGB laser beam 33 to strike the horizontal mirror 24, while the purpose of the horizontal mirror 24 and vertical mirror 22 is to scan the RGB laser beam 33 across the display surface in a scan pattern designed to reproduce the desired still or moving images. The overall dimensions of the vertical mirror 22 may be, for example, 7.94 mm in length, 2.34 mm in depth, and 0.67 mm in height; the overall dimensions of the horizontal mirror 24 may be, for example, 4.44 mm in length, 2.94 mm in depth, and 0.67 mm in height. Naturally, the vertical mirror 22 and horizontal mirror 24 may have other dimensions, and the given dimensions are just examples.

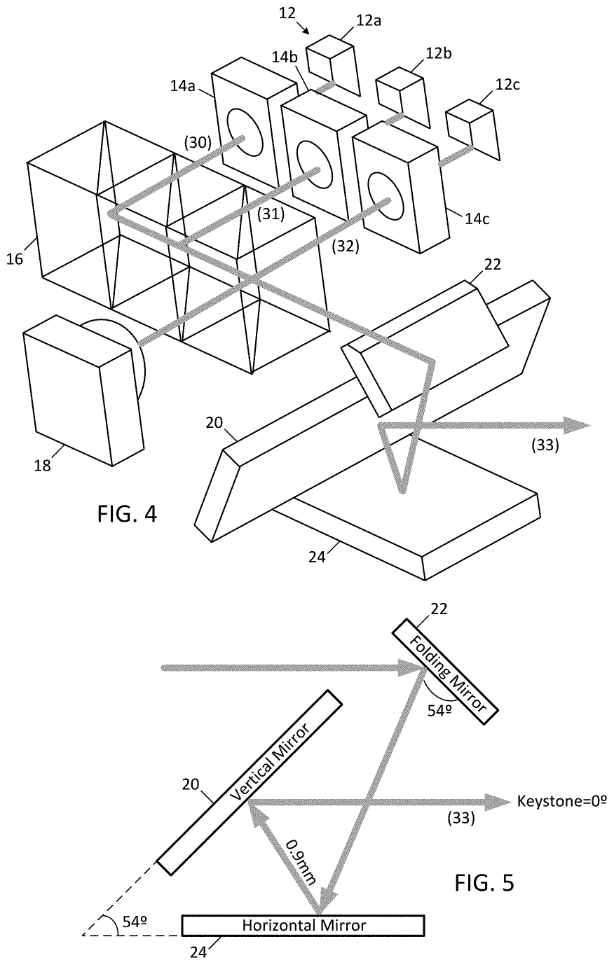

Note that, instead of the beam splitter 16, as shown in FIG. 3, three separate dichroic beam combiners 16a′, 16b′, and 16c′ may be used to reproduce the RGB laser beam 33 and its illustrated path. Understand that, as compared to the beam splitter 16 which is a single component formed from sub-components bonded together, the dichroic beam combiners 16a′, 16b′, and 16c′ are separate, discrete components. The overall dimension of each dichroic beam combiner 16a′, 16b′, and 16c′ may be 2.6 mm in length, 0.5 mm in depth, and 3.2 mm in height, for example. Naturally, dichroic beam combiners 16a′, 16b′, and 16c′ may have other dimensions, and the given dimensions are just examples. The dichroic beam combiners 16a′, 16b′, and 16c′ have the same functional operation as the beam splitter 16 described above.

Turning now to FIG. 4, the geometry of the vertical mirror 20, horizontal mirror 24, and folding mirror 22 is now described. The RGB laser beam 33 is aimed by the beam splitter 16 to pass over the top of the vertical mirror 20 to strike the folding mirror 22, which reflects the RGB laser beam 33 onto the horizontal mirror 24, which then reflects the RGB laser beam 33 onto the vertical mirror 20, which reflects the RGB laser beam 33 out the exit window 26 on the housing 11 and onto the display surface.

Sample angles for this path taken by the RGB laser beam 33 may be seen in FIG. 5, where the folding mirror 32 reflects the RGB laser beam 33 at an angle of 54° toward the horizontal mirror 24, and the horizontal mirror 24 reflects the RGB laser beam 33 at an angle of 54° toward the vertical mirror. The vertical mirror 20 is arranged to reflect the RGB laser beam 33 in a direction parallel to the plane in which the horizontal mirror 24 lies, and therefore directly out the exit window 26 without any keystone. In this arrangement, it may be observed that the path traveled by the RGB laser beam 33 between the centers of the horizontal mirror 24 and vertical mirror 20 is about 0.9 mm. The mechanical opening angle of the vertical mirror 20 is ±5°, and the mechanical opening angle of the horizontal mirror 24 is ±12°.

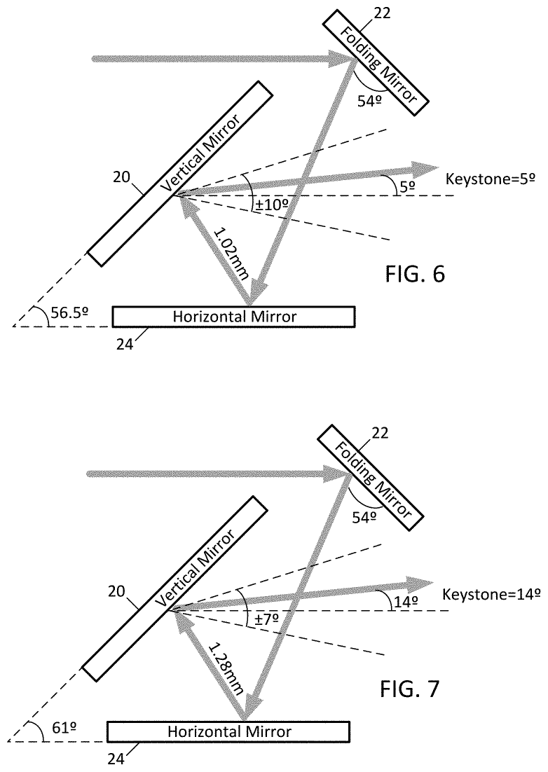

In some instances, it may be desired for the RGB laser beam 33 to exit the exit window with keystone. For example, in FIG. 6, the folding mirror 32 reflects the RGB laser beam 33 at an angle of 54° toward the horizontal mirror 24, and the horizontal mirror 24 reflects the RGB laser beam 33 at an angle of 56.5° toward the vertical mirror, and the vertical mirror 20 reflects the RGB laser beam 33 out the exit window 26 at a keystone angle of 5°, which permits ±10° in mechanical opening angle of the vertical mirror 20. In this arrangement, it may be observed that the path traveled by the RGB laser beam 33 between the centers of the horizontal mirror 24 and vertical mirror 20 is about 1.02 mm.

As another example, in FIG. 7, the folding mirror 32 reflects the RGB laser beam 33 at an angle of 54° toward the horizontal mirror 24, and the horizontal mirror 24 reflects the RGB laser beam 33 at an angle of 61° toward the vertical mirror, and the vertical mirror 20 reflects the RGB laser beam 33 out the exit window 26 at a keystone angle of 14°, which permits ±7° in mechanical opening angle of the vertical mirror 20. In this arrangement, it may be observed that the path traveled by the RGB laser beam 33 between the horizontal mirror 24 and vertical mirror 20 is about 1.28 mm.

From the above, it is to be noticed that the distance between the centers of the horizontal mirror 24 and vertical mirror 20 changes as the keystone angle changes. The larger the keystone, the larger the distance between the centers of the horizontal mirror 24 and vertical mirror 20, and vice versa.

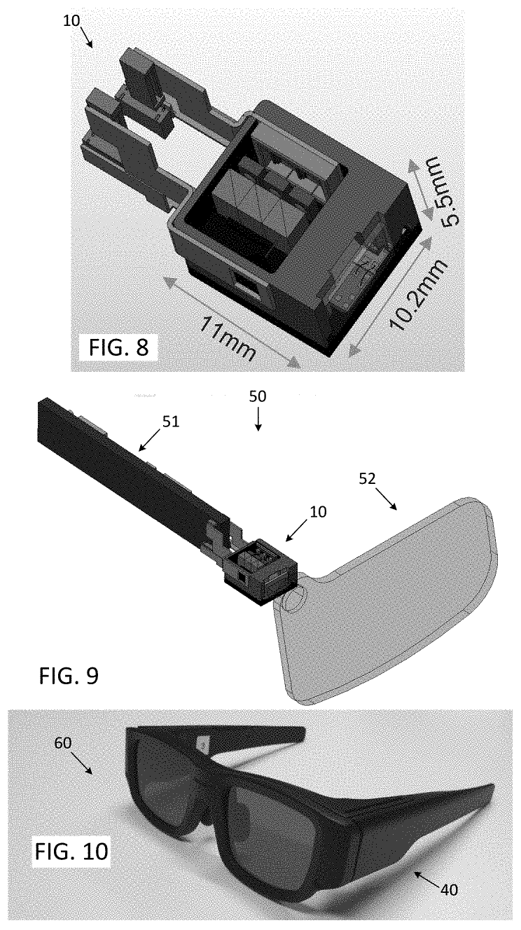

A perspective view of the compact optical module 10 may be seen in FIG. 8, where it can be seen that the housing 11 has dimensions of 10.2 mm in width, 11 mm in depth, and 5.5 mm in height.

A potential augmented reality unit 40 is shown in FIG. 9, where it can be observed that the compact optical module 10 is installed and electrically connected to the end of a printed circuit board 51 that includes drivers for the mirrors and RGB laser package within the compact optical module 10. A target surface 52 is adjacent the exit window of the compact optical module 10, and therefore in operation, images are formed on the target surface 52 by the compact optical module 10.

This augmented reality unit 40 may be installed into a pair of augmented reality glasses 60, as shown in FIG. 10, where it can be observed that the compact optical module 10 is sufficiently small such that the augmented reality glasses 60 appear to be a normal pair of eyeglasses.

While the disclosure has been described with respect to a limited number of embodiments, those skilled in the art, having benefit of this disclosure, will appreciate that other embodiments can be envisioned that do not depart from the scope of the disclosure as disclosed herein. Accordingly, the scope of the disclosure shall be limited only by the attached claims.

1. An optical package, comprising:
a laser unit containing one or more laser diodes within a single package;
one or more lenses adjacent the laser unit and configured to collimate laser light emitted by the one or more laser diodes of the laser unit;
a beam combiner configured to combine the laser light from the one or more laser diodes into a single laser beam and to also output a lower power feedback beam;
a movable mirror apparatus;
a fixed folding mirror upon which the single laser beam output by the beam combiner impinges and which is configured to reflect the single laser beam toward the movable mirror apparatus; and
wherein the movable mirror apparatus is configured to direct the single laser beam through an exit window and to scan the single laser beam in a scan pattern to form at least one desired image on a target adjacent the optical package.

2. The optical package of claim 1, wherein the laser unit contains red, green, and blue laser diodes within a single package that lases to generate red, green, and blue laser light that is initially shone through a prism within the laser unit and which exit the prism to impinge upon the one or more lenses; wherein the one or more lenses comprise first, second, and third lenses upon which the red, green, and blue lasers impinge; and wherein the single laser beam is a RGB laser beam.

3. The optical package of claim 2, wherein the red, green, and blue laser diodes are each formed within respective dies contained within the single package of the laser unit; and wherein the respective die into which the red, green, and blue laser diodes are formed are separated from one another by free space within the laser unit.

4. The optical package of claim 2, wherein the movable mirror apparatus includes a horizontal mirror upon which the RGB laser beam, as reflected by the folding mirror, impinges, wherein the horizontal mirror reflects the RGB laser beam toward a vertical mirror that reflects the RGB laser beam out an exit window in the optical package.

5. The optical package of claim 4, wherein the horizontal mirror is driven at resonance and the vertical mirror is driven linearly.

6. The optical package of claim 4, wherein the vertical mirror is arranged such that the RGB laser beam exits the exit window at a desired keystone angle.

7. The optical package of claim 1, further comprising a photodiode receiving the low power feedback beam.

8. The optical package of claim 1, wherein the beam combiner comprises a single beam splitter unit arranged such that the laser light emitted by the one or more laser diodes enters into outputs of the beam splitter, such that the low power feedback beam exits from another output of the beam splitter, and such that the single laser beam exists from the input of the beam splitter.

9. The optical package of claim 1, wherein the beam combiner comprises first, second, and third discrete dichroic beam combiners spaced apart from one another.

10. An augmented reality package, comprising:
a printed circuit board containing laser driver circuitry and mirror driver circuitry;
a compact optical package mechanically connected to the printed circuit board and electrically connected to the laser driver circuitry and mirror driver circuitry;
wherein the compact optical package comprises:
an RGB laser unit containing red, green, and blue laser diodes within a single package, the RGB laser unit electrically connected to the laser driver circuitry;
three lenses adjacent the RGB laser unit and configured to collimate red, green, and blue laser light emitted by the red, green, and blue laser diodes of the RGB laser unit;
a beam combiner configured to combine the red, green, and blue laser light into a single RGB laser beam and to also output a lower power feedback beam;
a movable mirror apparatus electrically connected to the mirror driver circuitry;
a fixed folding mirror upon which the single RGB laser beam output by the beam splitter impinges and configured to reflect the single RGB laser beam toward the movable mirror apparatus; and
wherein the movable mirror apparatus is configured to, under control of the mirror driver circuitry, direct the single RGB laser beam through an exit window and to scan the single RGB laser beam in a scan pattern to form at least one desired image on a target of the augmented reality package.

11. The augmented reality package of claim 10, wherein the red, green, and blue laser diodes are each formed within respective dies contained within the single package of the RGB laser unit; and wherein the respective die into which the red, green, and blue laser diodes are formed are separated from one another by free space within the RGB laser unit.

12. The augmented reality package of claim 10, wherein the movable mirror apparatus includes a horizontal mirror upon which the RGB laser beam, as reflected by the folding mirror, impinges, wherein the horizontal mirror reflects the RGB laser beam toward a vertical mirror that reflects the RGB laser beam out an exit window in the compact optical package toward the target.

13. The augmented reality package of claim 12, wherein the horizontal mirror is driven at resonance and the vertical mirror is driven linearly.

14. The augmented reality package of claim 13, wherein the vertical mirror is arranged such that the RGB laser beam exits the exit window at a desired keystone angle.

15. The augmented reality package of claim 10, further comprising a photodiode receiving the low power feedback beam.

16. The augmented reality package of claim 10, wherein the beam combiner comprises a single beam splitter unit arranged such that the red, green, and blue laser light enters into outputs of the beam splitter, such that the low power feedback beam exits from another output of the beam splitter, and such that the single RGB laser beam exists from the input of the beam splitter.

17. The augmented reality package of claim 10, wherein the beam combiner comprises first, second, and third discrete dichroic beam combiners spaced apart from one another.
